(19) United States
(12) Patent Application Publication
(10) Pub. No.: US 2026/0282522 A1
(43) Pub. Date: Sep. 17, 2026

(54) CHIP COMPONENT

(71) Applicant: ROHM CO., LTD., Kyoto (JP)

(72) Inventor: Hiroyuki OKADA, Kyoto (JP)

(73) Assignee: ROHM CO., LTD., Kyoto (JP)

(21) Appl. No.: 19/668,653

(22) Filed: May 5, 2026

Related U.S. Application Data
(63) Continuation of application No. PCT/JP2024/038311, filed on Oct. 28, 2024.

(30) Foreign Application Priority Data
Nov. 7, 2023 (JP) 2023-189978

(51) Int. Cl. H10D 84/00; H10D 1/68

(52) U.S. Cl. CPC H10D 84/212; H10D 1/714; H10D 1/716

(57) ABSTRACT

A chip component includes: a substrate; a first capacitor structure formed on the substrate; and a second capacitor structure formed on the substrate. The first capacitor structure and the second capacitor structure are electrically connected in parallel. The first capacitor structure is a trench capacitor. In one example, the first capacitor structure has a greater capacitance than the second capacitor structure. The substrate includes a semiconductor. In one example, the substrate contains silicon.

### TECHNICAL FIELD

The present disclosure relates to a chip component.

### BACKGROUND ART

JP-A-2017-195322 discloses a chip capacitor including a substrate; a first conductor film and a first pad film formed on the substrate; a dielectric film formed on the first conductor film; and a second conductor film formed on the dielectric film and including a second connection region and a second capacitor formation region. The first conductor film includes a first connection region and a first capacitor formation region. A first external electrode is bonded to the first connection region of the first conductor film, and a second external electrode is bonded to the second connection region of the second conductor film.

### BRIEF DESCRIPTION OF THE DRAWINGS

FIG. 1 is a schematic perspective view showing a chip component according to a first embodiment of the present disclosure.

FIG. 2 is a schematic exploded perspective view showing the chip component according to the first embodiment of the present disclosure.

FIG. 3 is a schematic partial plan view showing the chip component according to the first embodiment of the present disclosure.

FIG. 4 is a circuit diagram showing the chip component according to the first embodiment of the present disclosure.

FIG. 5 is a schematic partially enlarged plan view showing the chip component according to the first embodiment of the present disclosure.

FIG. 6 is a schematic partially enlarged plan view showing the chip component according to the first embodiment of the present disclosure.

FIG. 7 is a schematic partially enlarged plan view showing the chip component according to the first embodiment of the present disclosure.

FIG. 8 is a schematic partial cross-sectional view showing the chip component according to the first embodiment of the present disclosure.

FIG. 9 is a schematic partial cross-sectional view showing the chip component according to the first embodiment of the present disclosure.

FIG. 10 is a schematic partial plan view showing a first variation of the chip component according to the first embodiment of the present disclosure.

FIG. 11 is a schematic partial plan view showing a second variation of the chip component according to the first embodiment of the present disclosure.

### DETAILED DESCRIPTION OF EMBODIMENTS

The following describes preferred embodiments of the present disclosure in detail with reference to the drawings.

The terms such as "first", "second" and "third" in the present disclosure are used merely for identification, and are not intended to impose orders on the elements accompanied with these terms.

In the present disclosure, the phrases "an object A is formed in an object B" and "an object A is formed on an object B" include, unless otherwise specified, "an object A is formed directly in/on an object B" and "an object A is formed in/on an object B with another object interposed between the object A and the object B". Similarly, the phrases "an object A is disposed in an object B" and "an object A is disposed on an object B" include, unless otherwise specified, "an object A is disposed directly in/on an object B" and "an object A is disposed in/on an object B with another object interposed between the object A and the object B". Similarly, the phrase "an object A is located on an object B" includes, unless otherwise specified, "an object A is located on an object B, in contact with the object B" and "an object A is located on an object B with another object interposed between the object A and the object B". Further, the phrase "an object A overlaps with an object B as viewed in a certain direction" includes, unless otherwise specified, "an object A overlaps with the entirety of an object B" and "an object A overlaps with a part of an object B". In the present disclosure, the phrase "a plane A faces (a first side or a second side) in a direction B" is not limited to the case where the angle of the plane A with respect to the direction B is 90°, but also includes the case where the plane A is inclined to the direction B.

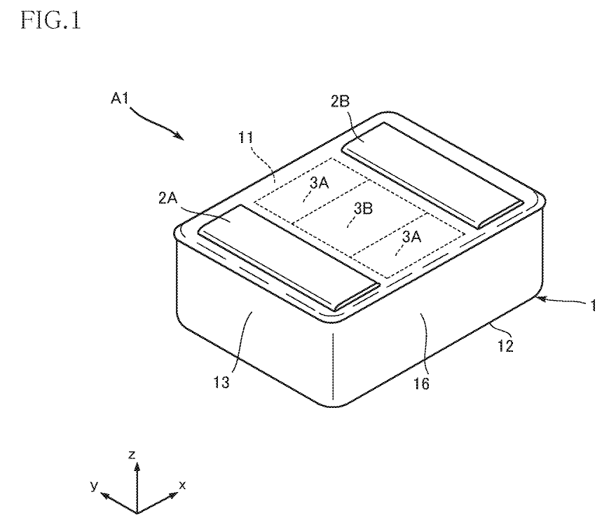

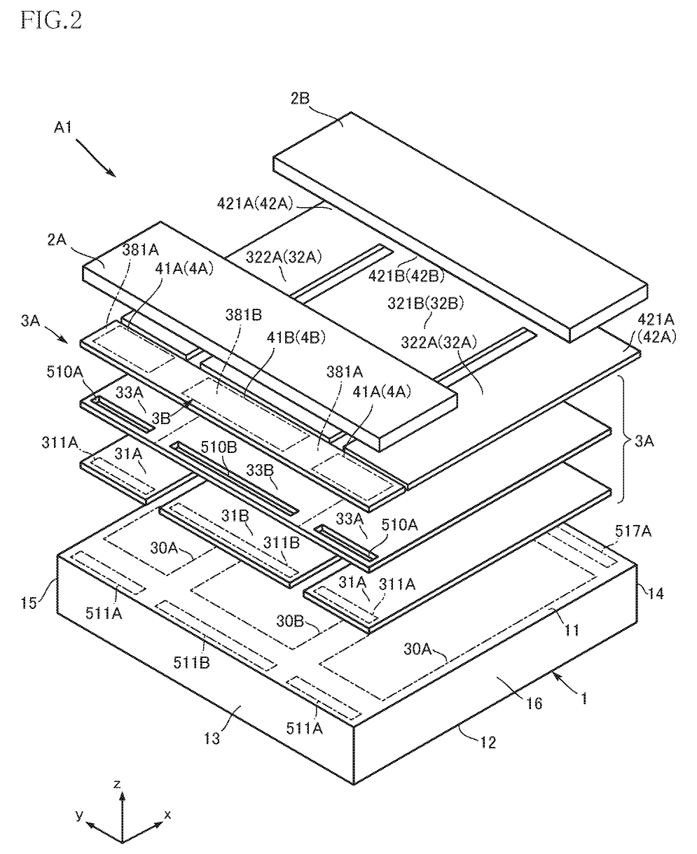

FIGS. 1-9 show a chip component according to a first embodiment of the present disclosure. FIG. 1 is a schematic perspective view of a chip component A1 of the present embodiment. FIG. 2 is a schematic exploded perspective view of the chip component A1. In FIGS. 1 and 2, the longitudinal direction of the chip component A1, which has a rectangular parallelepiped shape, is defined as a second direction x, the width direction of the chip component A1 is defined as a third direction y, and the thickness direction of the chip component A1 is defined as a first direction z.

The chip component A1 is formed to have a rectangular parallelepiped shape. The length in the second direction x may be at least 0.4 mm and at most 2 mm, for example. The width in the third direction y may be at least 0.2 mm and at most 2 mm, for example. The thickness in the first direction z may be at least 0.05 mm and at most 0.5 mm, for example.

The chip component A1 may be a small electronic component referred to as a 1608 (1.6 mm × 0.8 mm) chip, a 1005 (1.0 mm × 0.5 mm) chip, a 0603 (0.6 mm × 0.3 mm) chip, a 0402 (0.4 mm × 0.2 mm) chip, or a 03015 (0.3 mm × 0.15 mm) chip, for example, using a size designation (length (mm) in the second direction x × width (mm) in the third direction y).

The chip component A1 includes a substrate 1, a first external electrode 2A, and a second external electrode 2B.

The substrate 1 forms the base of the chip component A1. As described in detail below, a plurality of films, such as insulating films and metal films, are stacked on each other on the substrate 1 to form the chip component A1. The substrate 1 has a rectangular parallelepiped shape, and has substantially the same size as the chip component A1. The substrate 1 has a substrate obverse surface 11, a substrate reverse surface 12, and four substrate side surfaces 13 to 16. The substrate obverse surface 11 is the obverse surface of the chip component A1, and the substrate reverse surface 12 is the reverse surface of the chip component A1. In plan view along the first direction z (hereinafter, simply "plan view"), the four substrate side surfaces 13 to 16 surround the substrate obverse surface 11. The four substrate side surfaces 13 to 16 may include a substrate side surface 13 and a substrate side surface 14 that are spaced apart from each other in the second direction x, and a substrate side surface 15 and a substrate side surface 16 that are spaced apart from each other in the third direction y. In other words, the substrate side surface 13 and the substrate side surface 14 may be side surfaces that extend in parallel to each other in the third direction y, and the substrate side surface 15 and the substrate side surface 16 may be side surfaces that extend in parallel to each other in the second direction x. The substrate side surface 13, the substrate side surface 14, the substrate side surface 15, and the substrate side surface 16 may be referred to as a first end face, a second end face, a third end face, and a fourth end face, respectively.

The first external electrode 2A and the second external electrode 2B are formed on the substrate obverse surface 11. The first external electrode 2A and the second external electrode 2B are spaced apart from each other in the second direction x. In the present embodiment, the first external electrode 2A and the second external electrode 2B form two terminals of the chip component A1, and a current flows between the first external electrode 2A and the second external electrode 2B in a lateral direction along the substrate obverse surface 11 of the substrate 1. Thus, the chip component A1 may be referred to as a lateral chip component. The lateral chip component A1 can be used by flip-chip bonding to a mounting substrate. The first external electrode 2A and the second external electrode 2B may be referred to as a first terminal electrode and a second terminal electrode, or as a first external terminal and a second external terminal. The first external electrode 2A and the second external electrode 2B may be formed by electroless plating.

The first external electrode 2A is formed in a region on the substrate obverse surface 11 of the substrate 1, where the region is spaced inward from the four substrate side surfaces 13 to 16. In plan view, the first external electrode 2A has a rectangular shape elongated in a direction along the substrate side surface 13. The first external electrode 2A is spaced apart from the substrate side surface 13, the substrate side surface 14, the substrate side surface 15, and the substrate side surface 16 of the substrate 1. Note that the first external electrode 2A may overlap with the substrate side surface 13, the substrate side surface 15, and the substrate side surface 16 of the substrate 1 so as to partially cover the substrate side surfaces 13, 15, and 16 of the substrate 1.

The second external electrode 2B is formed in a region on the substrate obverse surface 11 of the substrate 1, where the region is spaced inward from the four substrate side surfaces 13 to 16. In plan view, the second external electrode 2B has a rectangular shape elongated in a direction along the substrate side surface 14. The second external electrode 2B is spaced apart from the substrate side surface 14, the substrate side surface 13, the substrate side surface 15, and the substrate side surface 16 of the substrate 1. Note that the second external electrode 2B may overlap with the substrate side surface 14, the substrate side surface 15, and the substrate side surface 16 of the substrate 1 so as to partially cover the substrate side surfaces 14, 15, and 16 of the substrate 1.

FIG. 2 is a schematic exploded view of the chip component A1. In FIG. 2, only the main elements of the chip component A1 are shown. Thus, the chip component A1 may include elements other than the constituent elements shown in FIG. 2.

As seen from FIG. 1, the chip component A1 may include the substrate 1, two first capacitor structures 3A, and a second capacitor structure 3B. In addition, as seen from FIG. 2, the chip component A1 may include a first electrode film 4A, the first external electrode 2A, and the second external electrode 2B. The respective numbers of first capacitor structures 3A and second capacitor structures 3B are not limited. It is possible to provide one or more first capacitor structures 3A. Similarly, it is possible to provide one or more second capacitor structures 3B. In the present embodiment, two first capacitor structures 3A and one second capacitor structure 3B is are provided, as noted above. The two first capacitor structures 3A are spaced apart from each other in the third direction y with the single second capacitor structure 3B therebetween.

FIG. 4 is a circuit diagram showing the chip component A1. In the chip component A1, the first capacitor structure 3A and the second capacitor structure 3B are electrically connected in parallel. In the present embodiment, two first capacitor structures 3A and a single second capacitor structure 3B are electrically connected in parallel. As described below, the two first capacitor structures 3A and the single second capacitor structure 3B are electrically connected via the first external electrode 2A. Further, the two first capacitor structures 3A and the single second capacitor structure 3B are electrically connected via the second external electrode 2B.

### First Capacitor Structure 3A

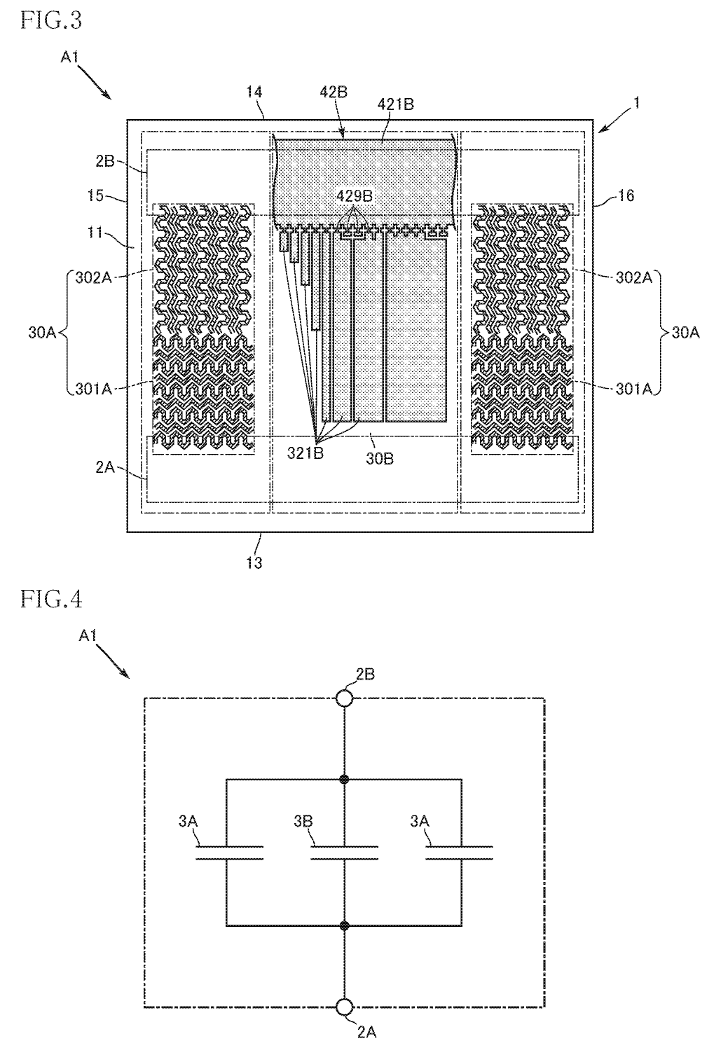

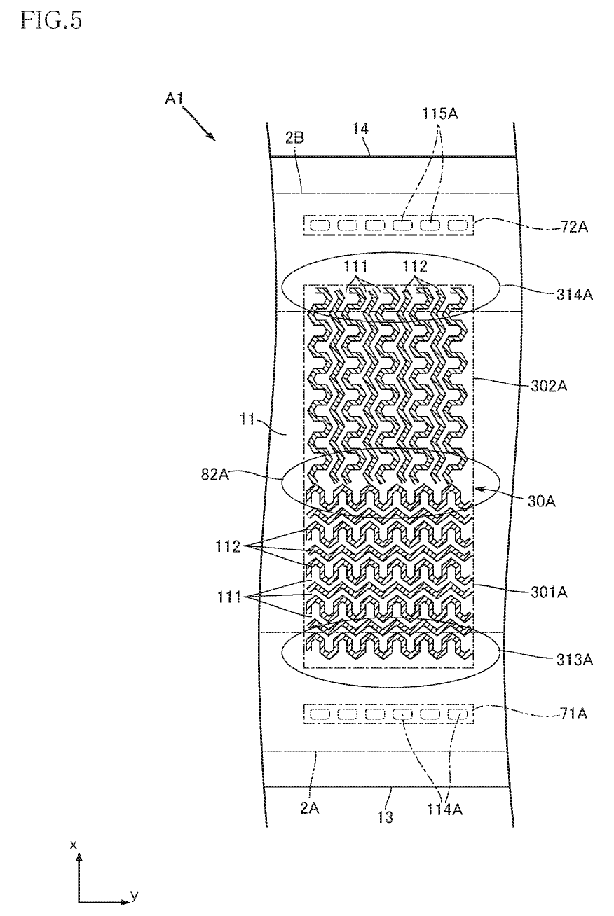

As shown in FIGS. 2 and 3, for example, the substrate obverse surface 11 of the substrate 1 has at least one first capacitor section 30A formed thereon. The first capacitor section 30A is an area on the substrate 1 where the main part of the first capacitor structure 3A (i.e., the part having a three-layer structure with an electrode, a capacitor film, and an electrode and serving as a passive element) is formed, and may be referred to as a capacitor region. In FIGS. 2 and 3, the first capacitor section 30A is indicated as a closed region surrounded by one-dot chain lines and clearly distinguished from a portion other than the capacitor section on the substrate obverse surface 11. However, the first capacitor section 30A is not clearly sectioned on the substrate obverse surface 11 in plan view, for example, and may be defined as a visually recognizable portion where the main part of the first capacitor structure 3A is arranged. The first capacitor structure 3A of the present embodiment is configured as a trench capacitor, as seen from FIGS. 3 and 5, for example. The capacitance of the first capacitor structure 3A configured as a trench capacitor may be at least 100 pF and at most 1 μF.

Two first capacitor sections 30A are formed on the opposite sides of the substrate obverse surface 11 in the third direction y. As shown in FIG. 3, the first capacitor sections 30A may be defined as rectangular regions elongated in the second direction x. The number of first capacitor sections 30A may be one or more. When the number of first capacitor sections 30A is two or more, they may be arranged adjacent to each other. In the present embodiment, each of the first capacitor sections 30A includes a first region 301A and a second region 302A that are adjacent to each other in the second direction x.

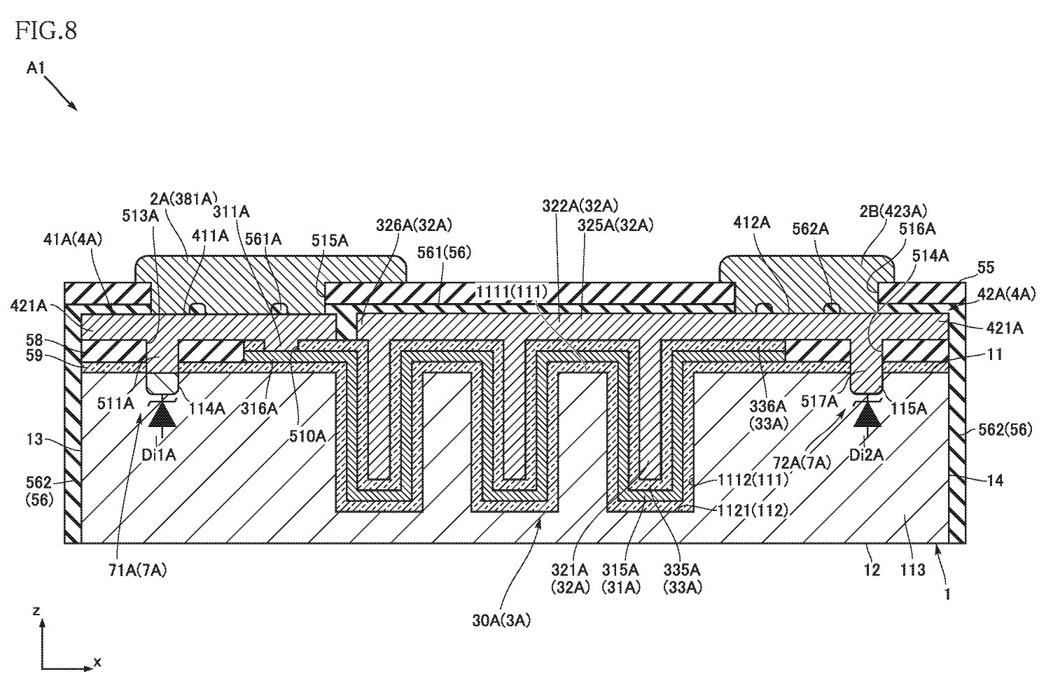

In addition to the first capacitor section 30A, a functional element section including functional elements other than capacitors is formed on the substrate obverse surface 11 of the substrate 1. The functional element section is a region on the substrate 1 where functional elements such as diodes, resistors, and inductors are formed, and may be referred to as a functional element region. As shown in FIG. 8, the functional element section of the present embodiment mainly includes diodes. Thus, the functional element section may be referred to as a first diode section 7A (see FIG. 8). In the following description, the functional element section is referred to as a first diode section 7A.

In plan view, a first diode section 7A is formed on the opposite ends of the substrate obverse surface 11 with the first capacitor section 30A therebetween. The first diode section 7A may be formed on the opposite ends (the end near the substrate side surface 15 and the end near the substrate side surface 16) of the substrate 1 in the third direction y. The first diode section 7A may comprise a plurality of first diode sections 7A. The plurality of first diode sections 7A may be spaced apart from each other with the first capacitor section 30A therebetween. The first diode section 7A of the present embodiment includes a first region 71A and a second region 72A. The first region 71A is formed in the area between the first capacitor section 30A and the substrate side surface 13 of the substrate 1. The second region 72A is formed in the area between the first capacitor section 30A and the substrate side surface 14 of the substrate 1. The first region 71A and the second region 72A extend along the substrate side surface 13 and the substrate side surface 14, respectively. In the third direction y, the length of each of the first region 71A and the second region 72A is substantially the same as the length of the first capacitor section 30A.

As shown in FIG. 8, the first capacitor structure 3A is formed on the substrate obverse surface 11 of the substrate 1 and covers or expands over the first capacitor section 30A. The first capacitor structure 3A includes a first internal electrode 31A, a first capacitor film 33A, and a second internal electrode 32A, where the first capacitor film 33A is located between the second internal electrode 32A and the first internal electrode 31A in the first direction z. The first internal electrode 31A, the first capacitor film 33A and the second internal electrode 32A may be formed as films or plates. The first internal electrode 31A has a size (planar size) smaller than that of the substrate 1 and larger than that of the second internal electrode 32A. The peripheral portion of the first capacitor film 33A is formed with a first capacitor contact hole 510A that makes contact with the first internal electrode 31A. The first internal electrode 31A, the second internal electrode 32A, and the first capacitor film 33A may be formed by sputtering or CVD, for example.

The first electrode film 4A includes a first electrode film 41A and a second electrode film 42A. The first electrode film 41A and the second electrode film 42A may be formed by sputtering. In the example illustrated in FIG. 8, the first electrode film 41A is smaller in length than the second electrode film 42A in the direction x.

The first electrode film 41A has contact portions for the first internal electrode 31A and the first region 71A. The first electrode film 41A electrically connects the first external electrode 2A to the first internal electrode 31A and the first region 71A. A lower contact portion 311A and a first diode contact portion 511A are shown as contact portions of the first electrode film 41A for the first internal electrode 31A and the first region 71A. The first electrode film 41A includes a first pad 411A. The first pad 411A is a portion that is electrically connected to the first external electrode 2A.

The second electrode film 42A has a contact portion for the second region 72A. The second electrode film 42A electrically connects the second external electrode 2B and the second region 72A. In FIG. 2, a second diode contact portion 517A is shown as a contact portion of the second electrode film 42A for the second region 72A. The second electrode film 42A includes a base portion 421A.

As shown in FIG. 8, the base portion 421A is a portion of the second electrode film 42A to which the second external electrode 2B is connected. In FIG. 2, a first external contact portion 381A (a region surrounded by two-dot chain lines) is shown as a contact portion of the first external electrode 2A for the first electrode film 41A. The base portion 421A is formed to have a substantially rectangular shape elongated in the third direction y (see also FIG. 2).

In the present embodiment, the second electrode film 42A and the second internal electrode 32A are formed integrally to constitute a single layer.

The first external electrode 2A and the second external electrode 2B are formed on the first electrode film 4A. The first external electrode 2A has a first external contact portion 381A, and is connected to the first electrode film 41A via the first external contact portion 381A. The second external electrode 2B has a second external contact portion 423A as noted above, and is connected to the second electrode film 42A via the second external contact portion 423A.

Next, as shown in FIGS. 2, 3, 5, and 8, two first capacitor sections 30A are formed on the opposite sides of the substrate obverse surface 11 of the substrate 1 in the third direction y. The portion of the substrate 1 other than the first capacitor sections 30A may be defined as a substrate main portion 10. In the present embodiment, the substrate main portion 10 has a substantially square annular (closed-frame) portion surrounding the first capacitor sections 30A in plan view. The substrate main portion 10 has a frame shape surrounding the first capacitor sections 30A, and may be referred to as a frame portion of the substrate 1.

The first internal electrode 31A includes a first main portion 315A and a first peripheral portion 316A. The first main portion 315A is formed within the first capacitor section 30A. The first peripheral portion 316A is formed integrally with the first main portion 315A on the substrate main portion 10 (the frame portion of the substrate 1) around the first capacitor section 30A. The first peripheral portion 316A is a portion extending from the first main portion 315A to the periphery of the first capacitor section 30A, and may be referred to as a lead-out portion of the first internal electrode 31A.

The first peripheral portion 316A may include a plurality of portions defined separately based on the position relative to the first capacitor section 30A. The first capacitor section 30A is a closed region surrounded by the first peripheral portion 316A.

The first capacitor film 33A includes a second main portion 335A and a second peripheral portion 336A. The second main portion 335A is formed within the first capacitor section 30A. The second peripheral portion 336A is formed integrally with the second main portion 335A on the first peripheral portion 316A around the first capacitor section 30A. The second peripheral portion 336A is a portion extending from the second main portion 335A to the periphery of the first capacitor section 30A, and may be referred to as a lead-out portion of the first capacitor film 33A.

The second internal electrode 32A is formed to have a shape covering the first capacitor section 30A. In the present embodiment, the second internal electrode 32A is formed to have a rectangular shape covering the entirety of the first capacitor section 30A. The second internal electrode 32A integrally includes a main portion 325A and a peripheral portion 326A. The main portion 325A may face the first capacitor section 30A in the first direction z.

The peripheral portion 326A may extend from the main portion 325A to the periphery of the first capacitor section 30A and surround the first capacitor section 30A. In the present embodiment, the first peripheral portion 316A and the second peripheral portion 336A are formed outside the peripheral portion 326A of the second internal electrode 32A in plan view, and surround the peripheral portion 326A that surrounds the first capacitor section 30A.

The lower contact portion 311A is a contact portion of the first electrode film 41A for the first internal electrode 31A, and is formed on the first peripheral portion 316A of the first internal electrode 31A. The lower contact portion 311A may be formed in an open-ring shape that is open on one side of the first capacitor section 30A in the second direction x and closed on the other side in the second direction x, and that surrounds the first capacitor section 30A.

The first diode contact portion 511A is a contact portion of the first electrode film 41A for the first region 71A. The first diode contact portion 511A overlaps with the first external electrode 2A. The first diode contact portion 511A may be formed in a region below the first external electrode 2A. As seen from FIG. 2, the first diode contact portion 511A is formed in a band shape that extends along the substrate side surface 13 of the substrate 1 in the third direction y, and that is parallel to the substrate side surface 13.

The second diode contact portion 517A is a contact portion of the second electrode film 42A for the second region 72A. The second diode contact portion 517A overlaps with the second external electrode 2B. The second diode contact portion 517A may be formed in a region below the second external electrode 2B. As seen from FIG. 2, the second diode contact portion 517A is formed in a band shape that extends along the substrate side surface 14 of the substrate 1 in the third direction y, and that is parallel to the substrate side surface 14.

The first electrode film 41A is located on one side of the first capacitor section 30A in the x direction.

### First Capacitor Section 30A

FIG. 5 is an enlarged view showing a main part of the chip component A1, including the first capacitor section 30A. FIG. 8 is a schematic cross-sectional view showing the chip component A1. For clarity, in FIG. 5, trenches 112 are hatched, and the first external electrode 2A and the second external electrode 2B are shown as transparent with dashed lines. In FIG. 5, constituent elements necessary for description and the reference numerals thereof are extracted and shown. FIG. 8 schematically shows the layer structure on the substrate obverse surface 11 of the chip component A1, and does not show a cross section taken along any particular cutting line in FIG. 5. Note that FIG. 8 is a view for explaining the cross-sectional structure of the first capacitor section 30A in FIG. 5.

The chip component A1 is a composite element in which the first capacitor structure 3A, the second capacitor structure 3B, and the first diode section 7A are mounted on the common substrate 1. The substrate 1 may be a semiconductor substrate such as a silicon plate. Alternatively, the substrate 1 may be an insulating substrate such as a ceramic substrate or a glass substrate. The substrate 1 may have a thickness of at least 200 μm and at most 1000 μm.

In the first capacitor section 30A, a portion of the substrate 1 near the substrate obverse surface 11 is selectively removed, so that a plurality of walls 111 are formed by utilizing a portion of the substrate 1. The plurality of walls 111 extend in a longitudinal direction and are formed in a meandering stripe pattern in plan view. The plurality of walls 111 are formed across the entirety of the first capacitor section 30A.

A single first region 301A and a single second region 302A are formed adjacent to each other. In the present embodiment, the first region 301A and the second region 302A are formed adjacent to each other in the second direction x. More specifically, the first region 301A extends to bridge between a first overlap portion 313A (overlapping with the first external electrode 2A as viewed in plan) and an intermediate portion 82A, while the second region 302A extends to bridge between a second overlap portion 314A (overlapping with the second external electrode 2B as viewed in plan) and the intermediate portion 82A.

The walls 111 in the first region 301A are arranged in the second direction x and spaced apart from each other. The walls 111 in the second region 302A are arranged in the third direction y and spaced apart from each other. Thus, in each of the first region 301A and the second region 302A, the walls 111 are formed in a stripe pattern in plan view. The shape of each wall 111 is not particularly limited.

A plurality of trenches 112 are formed between the plurality of walls 111. The trenches 112 are portions of the substrate 1 where the material thereof has been removed, and are defined by the walls 111. The width of each trench 112 may be at least 2 μm and at most 8 μm. The trenches 112 may be formed by performing dry etching on the substrate 1, for example.

In the present embodiment, as shown in FIG. 8, the height of each wall 111 (the depth in the first direction z from the substrate obverse surface 11 to a bottom surface 1121 of each trench 112) may be at least 50 μm and at most 400 μm.

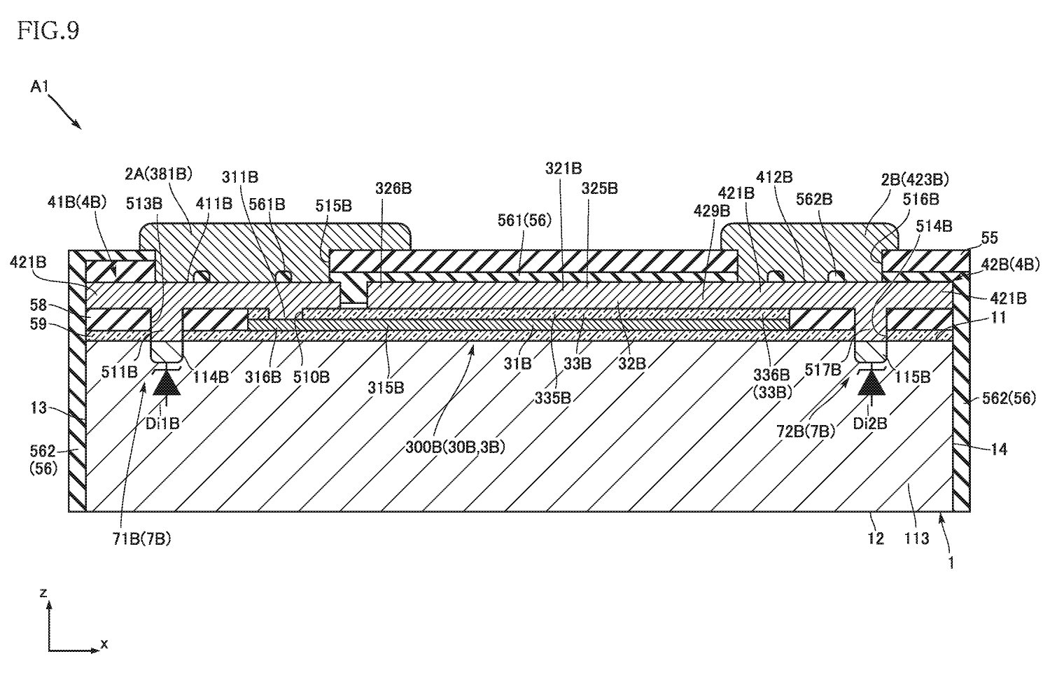

The substrate 1 is formed with a p-type base region 113 (see FIGS. 8-9), which is exposed from the substrate obverse surface 11 of the substrate 1. In the present embodiment, a p-type impurity is introduced throughout the thickness of the substrate 1 from the substrate obverse surface 11 to the substrate reverse surface 12 of the substrate 1. As a result, the base region 113 is formed in the entirety of the substrate 1, and the substrate 1 is regarded as a p-type substrate. The resistivity of the substrate 1 may be approximately 5·mΩ·cm due to the introduction of a p-type impurity. The base region 113 is not selectively formed in the first diode section 7A, and is formed across the entirety of the substrate 1 including the first capacitor section 30A. Thus, the walls 111 of the first capacitor section 30A and the substrate main portion 10 are formed by the p-type base region 113.

In the first region 71A, a plurality of first impurity regions 114A are formed in the surface portion of the base region 113. The first impurity regions 114A are n-type impurity regions. As shown in FIG. 5, the first impurity regions 114A are spaced apart from each other in the third direction y (the direction along the substrate side surface 13 of the substrate 1). In the second region 72A, a plurality of (six in FIG. 5) second impurity regions 115A are formed in the surface portion of the base region 113. The second impurity regions 115A are n-type impurity regions. The second impurity regions 115A are spaced apart from each other in the third direction y (the direction along the substrate side surface 14 of the substrate 1).

The first impurity regions 114A and the second impurity regions 115A may be formed to have the same depth and the same n-type impurity concentration. The n-type impurity concentration of each of the first impurity regions 114A and the second impurity regions 115A may be at least 1.0 × 10¹⁹cm⁻³and at most 1.0 × 10²¹ cm⁻³. The first impurity regions 114A and the second impurity regions 115A are formed with the same shape and the same area in plan view. Each of the first impurity regions 114A and the second impurity regions 115A extends in the third direction y in plan view, and is formed to have a rectangular shape whose four corners are cut off (a rectangle with rounded corners).

Each of the first impurity regions 114A forms a PN junction with the base region 113. The PN junction between the first impurity region 114A and the base region 113 forms a first Zener diode Di1A. Each of the second impurity regions 115A forms a PN junction with the base region 113. The PN junction between the second impurity region 115A and the base region 113 forms a second Zener diode Di2A. The first Zener diode Di1A and the second Zener diode Di2A are connected in reverse series via the base region 113. The first impurity region 114A and the second impurity region 115A are formed below the first external electrode 2A and the second external electrode 2B, respectively, so as to overlap with the first external electrode 2A and the second external electrode 2B in plan view. This prevents a depletion layer that extends from the PN junction between the first impurity region 114A and the base region 113 from overlapping with a depletion layer that extends from the PN junction between the second impurity regions 115A and the base region 113. Thus, a bidirectional Zener diode consisting of the first Zener diode Di1A and the second Zener diode Di2A is formed in the substrate 1.

An insulating film 59 is formed on the substrate obverse surface 11 of the substrate 1 so as to cover the entirety of the substrate obverse surface 11. The insulating film 59 is also formed on all surfaces of each wall 111 (the upper surface 1111 and side surfaces 1112 of each wall 111), in addition to the substrate obverse surface 11 which is a flat surface of the substrate 1. The insulating film 59 has end surfaces that coincide with the substrate side surfaces 13 to 16 of the substrate 1. The insulating film 59 may be an SiO₂ film or an SiN film. The insulating film 59 may have a thickness of at least 20,000 Å and at most 40,000 Å (at least 2 μm and at most 4 μm). The insulating film 59 may be formed by thermally oxidizing the substrate 1.

In the first capacitor section 30A, the first capacitor structure 3A is formed on the insulating film 59. The first capacitor structure 3A is formed along the upper surface 1111 and side surfaces 1112 of each wall 111. In other words, the first internal electrode 31A in the first capacitor structure 3A at least conforms to the uneven shape of each wall 111 in the width direction and the height direction. In the present embodiment, the first internal electrode 31A is formed as an electrode film, which is formed on the insulating film 59 and has one surface in contact with the upper surface 1111 and side surfaces 1112 of each wall 111 and another surface located at an equal distance from the upper surface 1111 and side surfaces 1112 of each wall 111. In other words, the first internal electrode 31A has a constant thickness along the upper surface 1111 and side surfaces 1112 of each wall 111.

The first capacitor film 33A is formed on the first internal electrode 31A, and the second internal electrode 32A is formed on the first capacitor film 33A. The first main portion 315A of the first internal electrode 31A faces the upper surface 1111 and side surfaces 1112 of each wall 111 as well as the bottom surface 1121 of each trench 112, and includes a counter electrode for the second internal electrode 32A. The first peripheral portion 316A of the first internal electrode 31A extends from the first main portion 315A onto the substrate obverse surface 11 of the substrate 1, and includes a contact portion for the first external electrode 2A. The first internal electrode 31A may be made of a semiconductor material such as polysilicon, or may be a metallic material containing Cu or Al. In the case of a metallic material, it may contain Cu, Al, AlSi, or AlCu. The first internal electrode 31A may have a thickness of at least 1,000 Å and at most 30,000 Å (at least 100 nm and at most 3000 nm).

The first capacitor film 33A is formed along the shape of the first internal electrode 31A, and conforms to the uneven shape of each wall 111 and each trench 112 in the width direction and the height direction. The first capacitor film 33A includes the second main portion 335A that covers the first main portion 315A of the first internal electrode 31A, and the second peripheral portion 336A that covers the first peripheral portion 316A of the first internal electrode 31A. The first capacitor film 33A may be an SiO₂ film or an SiN film, or may be a multilayer film thereof. For example, the first capacitor film 33A may be an SiO₂/SiN multilayer film or an SiO₂/SiN/SiO₂ multilayer film. The first capacitor film 33A may be an ON film or an ONO film, or may be a multilayer film thereof. Further, the first capacitor film 33A may be an insulating film made of a high dielectric material (high-k material). Examples of high dielectric materials include aluminum oxide (Al₂O₃), tantalum pentoxide (Ta₂O₅), titanium pentoxide (Ti₃O₅), and hafnium oxide (HfO₂), as well as perovskite compounds such as strontium titanate (SrTiO₃) and barium strontium titanate (BaₓSr₁₋ₓ)TiO₃. The first capacitor film 33A may have a thickness of at least 100 Å and at most 10,000 Å (at least 10 nm and at most 1000 nm).

The second internal electrode 32A is embedded in the trenches 112 and formed along the substrate obverse surface 11 of the substrate 1. The second internal electrode 32A integrally includes embedded portions 321A embedded in the trenches 112, and a flat portion 322A connected to the upper ends of the embedded portions 321A and formed flatly along the substrate obverse surface 11 of the substrate 1. The flat portion 322A forms the peripheral portion 326A of the second internal electrode 32A, which extends outward beyond the first capacitor section 30A. The flat portion 322A is integrally connected to the second electrode film 42A. The second internal electrode 32A may be made of a semiconductor material such as polysilicon, or may be a metallic material containing Cu or Al. In the case of a metallic material, it may contain Cu, Al, AlSi, or AlCu. The second internal electrode 32A (the flat portion 322A) may have a thickness of at least 4,000 Å and at most 30,000 Å (at least 400 nm and at most 3000 nm).

A first insulating film 58 is also formed on the substrate 1. The first insulating film 58 is formed on and covers the insulating film 59, the first internal electrode 31A, the first capacitor film 33A, and the second internal electrode 32A, as well as a third internal electrode 31B, a second capacitor film 33B, and a fourth internal electrode 32B which are described below. The first insulating film 58 has end surfaces that coincide with the substrate side surfaces 13 to 16 of the substrate 1. Thus, in the cross-sectional view shown in FIG. 8, the insulating film 59 and the first insulating film 58 may have lamination interfaces exposed on the extensions of the substrate side surfaces 13 to 16 of the substrate 1. The first insulating film 58 may be formed by CVD.

The first insulating film 58 is formed with a first capacitor contact hole 510A that exposes the first peripheral portion 316A of the first internal electrode 31A. The first capacitor contact hole 510A is also formed in the first capacitor film 33A.

The insulating film 59 and the first insulating film 58 are further formed with a first diode contact hole 513A that exposes the first region 71A and a second diode contact hole 514A that exposes the second region 72A. As seen from the first diode contact portion 511A, the first diode contact hole 513A is formed in a band shape elongated in the third direction y, and exposes the first Zener diodes Di1A collectively. Likewise, as seen from the second diode contact portion 517A, the second diode contact hole 514A is formed in a band shape elongated in the third direction y, and exposes the second Zener diodes Di2A collectively.

The first electrode film 41A and the second electrode film 42A are formed on the first insulating film 58 and spaced apart from each other.

Referring to FIG. 8, a portion of the base portion 421A of the first electrode film 41A is formed within the first diode contact hole 513A as a first diode contact portion 511A and another portion of the base portion 421A is formed within the first capacitor contact hole 510A. A portion of the first internal electrode 31A is formed within the first capacitor contact hole 510A as a lower contact portion 311A.

A portion of the base portion 421A of the second electrode film 42A is formed within the second diode contact hole 514A as the second diode contact portion 517A.

The first electrode film 41A and the second electrode film 42A may be made of a material containing Al. Such a material may be AlCu or AlSiCu, for example, and is preferably AlCu.

A surface insulating film 56 is also formed on the substrate 1. The surface insulating film 56 covers the first electrode film 41A and the second electrode film 42A, as well as a first electrode film 41B and a second electrode film 42B which are described below. The surface insulating film 56 may be an SiO₂ film or an SiN film. The surface insulating film 56 may have a thickness of at least 3,000 Å and at most 30,000 Å (at least 0.3 μm and at most 3 μm). The surface insulating film 56 integrally includes a first portion 561 that covers a region on the substrate obverse surface 11 of the substrate 1, and a second portion 562 that covers the substrate side surfaces 13 to 16 of the substrate 1. As a result, the substrate reverse surface 12 of the substrate 1 is exposed, and all the other surfaces of the substrate 1 are covered by the surface insulating film 56.

A surface protection film 55 is formed on the first portion 561 of the surface insulating film 56. The surface protection film 55 may be a resin film such as a polyimide film. The surface protection film 55 may have a thickness of at least 5,000 Å and at most 100,000 Å (at least 0.5 μm and at most 10 μm). The surface insulating film 56 may be formed by CVD. The surface protection film 55 may be formed by spraying.

The surface insulating film 56 and the surface protection film 55 are formed with a first pad opening 515A that exposes the base portion 421A of the first electrode film 41A as the first pad 411A. The surface insulating film 56 and the surface protection film 55 are formed with a second pad opening 516A that exposes the base portion 421A of the second electrode film 42A as a second pad 412A.

The first pad 411A is formed with a first covering portion 561A that selectively covers the first pad 411A. The second pad 412A is formed with a second covering portion 562A that selectively covers the second pad 412A. The first covering portion 561A and the second covering portion 562A may be made of the same material as the surface insulating film 56.

The first external electrode 2A is formed within the first pad opening 515A. The first external electrode 2A is connected to the first pad 411A as the first external contact portion 381A in the first pad opening 515A. As a result, the first external electrode 2A is electrically connected to the first internal electrode 31A and the first impurity regions 114A via the first electrode film 41A.

The second external electrode 2B is formed within the second pad opening 516A. The second external electrode 2B is connected to the second pad 412A as the second external contact portion 423A in the second pad opening 516A. As a result, the second external electrode 2B is electrically connected to the second internal electrode 32A and the second impurity regions 115A via the second electrode film 42A.

Each of the first external electrode 2A and the second external electrode 2B may be a Ni/Pd/Au multilayer film including an Ni film, a Pd film, and an Au film stacked in this order from the substrate 1. These films may be plating layers formed by plating deposition.

### Second Capacitor Structure 3B

The substrate obverse surface 11 of the substrate 1 has a second capacitor section 30B formed thereon. The second capacitor section 30B is an area on the substrate 1 where the main part of the second capacitor structure 3B (i.e., the part having a three-layer structure with an electrode, a capacitor film, and an electrode and serving as a passive element) is formed, and may be referred to as a capacitor region. In FIGS. 2 and 3, the second capacitor section 30B is indicated as a closed region surrounded by one-dot chain lines and clearly distinguished from a portion other than the capacitor section on the substrate obverse surface 11. However, the second capacitor section 30B is not clearly sectioned on the substrate obverse surface 11 in plan view, for example, and may be defined as a visually recognizable portion where the main part of the second capacitor structure 3B is arranged. The second capacitor structure 3B of the present embodiment is configured as a planar capacitor along the substrate obverse surface 11. The capacitance of the second capacitor structure 3B configured as a planar capacitor may be at least 1 pF and at most 100 pF.

The second capacitor section 30B is formed substantially at the center of the substrate obverse surface 11. As shown in FIG. 3, the second capacitor section 30B may be defined as a rectangular region elongated in the second direction x.

A functional element section is formed on the substrate obverse surface 11 of the substrate 1. As shown in FIG. 9, the functional element section may be referred to as a second diode section 7B. The following describes the second diode section 7B. The chip component A1 is not limited to a configuration including both of the first diode section 7A and the second diode section 7B, and may include only one of the first diode section 7A and the second diode section 7B. A configuration not including either the first diode section 7A or the second diode section 7B is also possible.

In plan view, a second diode section 7B is formed on the opposite ends of the substrate obverse surface 11 with the second capacitor section 30B therebetween. The second diode section 7B may be formed on the opposite ends (the end near the substrate side surface 15 and the end near the substrate side surface 16) of the substrate 1 in the third direction y. The second diode section 7B may comprise a plurality of second diode sections 7B. The plurality of second diode sections 7B may be spaced apart from each other with the second capacitor section 30B therebetween. The second diode section 7B of the present embodiment includes a first region 71B and a second region 72B. The first region 71B is formed in the area between the second capacitor section 30B and the substrate side surface 13 of the substrate 1. The second region 72B is formed in the area between the second capacitor section 30B and the substrate side surface 14 of the substrate 1. The first region 71B and the second region 72B extend along the substrate side surface 13 and the substrate side surface 14, respectively. In the third direction y, the length of each of the first region 71B and the second region 72B is substantially the same as the length of the second capacitor section 30B.

As shown in FIG. 9, the second capacitor structure 3B is formed on the substrate obverse surface 11 of the substrate 1 and covers the second capacitor section 30B. The second capacitor structure 3B includes a third internal electrode 31B, a second capacitor film 33B, and a fourth internal electrode 32B, where the second capacitor film 33B is located between the fourth internal electrode 32B and the third internal electrode 31B in the third direction z. The third internal electrode 31B, the second capacitor film 33B, and the fourth internal electrode 32B may be formed as films or plates. Each of the third internal electrode 31B and the second capacitor film 33B has a size (planar size) smaller than that of the substrate 1 and larger than that of the fourth internal electrode 32B. The peripheral portion of the second capacitor film 33B is formed with a first capacitor contact hole 510B that makes contact with the third internal electrode 31B. The third internal electrode 31B, the fourth internal electrode 32B, and the second capacitor film 33B may be formed by CVD. In the present embodiment, the first capacitor film 33A and the second capacitor film 33B are formed integrally to constitute a single layer.

A second electrode film 4B is formed on the second capacitor structure 3B and covers the second capacitor structure 3B. The second electrode film 4B may be formed as a conductive film. The second electrode film 4B includes a first electrode film 41B and a second electrode film 42B. The first electrode film 41B and the second electrode film 42B may be formed by sputtering.

The first electrode film 41B has contact portions for the third internal electrode 31B and the first region 71B. The first electrode film 41B electrically connects the first external electrode 2A to the third internal electrode 31B and the first region 71B. A lower contact portion 311B and a first diode contact portion 511B are shown as contact portions of the first electrode film 41B for the third internal electrode 31B and the first region 71B. The first electrode film 41B includes a first pad 411B. The first pad 411B is a portion that is electrically connected to the first external electrode 2A.

The second electrode film 42B has contact portions for the second region 72B. The second electrode film 42B electrically connects the second external electrode 2B to the fourth internal electrode 32B and the second region 72B. In FIG. 9, a second diode contact portion 517B is shown as a contact portion of the second electrode film 42B for the fourth internal electrode 32B and the second region 72B. The second electrode film 42B includes a base portion 421B. In the present embodiment, the second electrode film 42A and the second electrode film 42B are formed integrally and connected to each other.

The base portion 421B is a portion of the second electrode film 42B to which the second external electrode 2B is connected. In FIG. 3 (see also FIG. 9), a second external contact portion 423B surrounded by two-dot chain lines is shown as a contact portion of the second external electrode 2B for the second electrode film 42B. The base portion 421B is formed to have a substantially rectangular shape elongated in the third direction y.

In the present embodiment, the second electrode film 42B and the fourth internal electrode 32B are formed integrally to constitute a single layer.

The first external electrode 2A and the second external electrode 2B are formed on the second electrode film 4B. The first external electrode 2A has a first external contact portion381B, and is connected to the first electrode film 41B via the first external contact portion 381B. The second external electrode 2B has a second external contact portion 423B, and is connected to the second electrode film 42B via the second external contact portion 423B.

As shown in FIGS. 2, 3, 5, and 9, the second capacitor section 30B is formed substantially at the center of the substrate obverse surface 11 of the substrate 1. The portion of the substrate 1 other than the second capacitor section 30B may be defined as a substrate main portion 10. In the present embodiment, the substrate main portion 10 has a substantially square annular (closed-frame) portion surrounding the second capacitor section 30B in plan view. The substrate main portion 10 has a frame shape surrounding the second capacitor section 30B, and may be referred to as a frame portion of the substrate 1.

The third internal electrode 31B and the second capacitor film 33B have the same shape in plan view. The third internal electrode 31B includes a first main portion 315B and a first peripheral portion 316B. The first main portion 315B is formed within the second capacitor section 30B. The first peripheral portion 316B is formed integrally with the first main portion 315B on the substrate main portion 10 (the frame portion of the substrate 1) around the second capacitor section 30B. The first peripheral portion 316B is a portion extending from the first main portion 315B to the periphery of the second capacitor section 30B, and may be referred to as a lead-out portion of the third internal electrode 31B.

The first peripheral portion 316B may include a plurality of portions defined separately based on the position relative to the second capacitor section 30B. The second capacitor section 30B is a closed region surrounded by the first peripheral portion 316B.

The second capacitor film 33B includes a second main portion 335B and a second peripheral portion 336B. The second main portion 335B is formed within the second capacitor section 30B. The second peripheral portion 336B is formed integrally with second main portion 335B on the first peripheral portion 316B and around the second capacitor section 30B. The second peripheral portion 336B is a portion extending from the second main portion 335B to the periphery of the second capacitor section 30B, and may be referred to as a lead-out portion of the second capacitor film 33B.

The fourth internal electrode 32B is formed to have a shape covering the second capacitor section 30B. In the present embodiment, the fourth internal electrode 32B is formed to have a rectangular shape covering the entirety of the second capacitor section 30B. The fourth internal electrode 32B integrally includes a main portion 325B and a peripheral portion 326B. The main portion 325B may face the second capacitor section 30B in the first direction z.

The peripheral portion 326B may extend from the main portion 325B to the periphery of the second capacitor section 30B and surround the second capacitor section 30B. In the present embodiment, the first peripheral portion 316B and the second peripheral portion 336B are formed outside the peripheral portion 326B of the fourth internal electrode 32B in plan view, and surround the peripheral portion 326B that surrounds the second capacitor section 30B.

The lower contact portion 311B is a contact portion of the first electrode film 41B for the third internal electrode 31B, and is formed on the first peripheral portion 316B of the third internal electrode 31B. The lower contact portion 311B may be formed in an open-ring or -frame shape that is open on one side of the second capacitor section 30B and closed on the other side in the second direction x, so that it surrounds the second capacitor section 30B in a non-closed manner.

The first diode contact portion 511B is a contact portion of the first electrode film 41B for the first region 71B. The first diode contact portion 511B overlaps with the first external electrode 2A. The first diode contact portion 511B may be formed in a region below the first external electrode 2A. The first diode contact portion 511B is formed in a band shape that extends along the substrate side surface 13 of the substrate 1 in the third direction y, and that is parallel to the substrate side surface 13.

The second diode contact portion 517B is a contact portion of the second electrode film 42B for the second region 72B. The second diode contact portion 517B overlaps with the second external electrode 2B. The second diode contact portion 517B may be formed in a region below the second external electrode 2B. The second diode contact portion 517B is formed in a band shape that extends along the substrate side surface 14 of the substrate 1 in the third direction y, and that is parallel to the substrate side surface 14.

The first electrode film 41B is located on one side of the second capacitor section 30B in the x direction.

In the second capacitor section 30B, the substrate obverse surface 11 of the substrate 1 may be smooth.

The base region 113 is not selectively formed in the second diode section 7B, and is formed across the entirety of the substrate 1 including the second capacitor section 30B.

In the first region 71B, a plurality of first impurity regions 114B are formed in the surface portion of the base region 113. The first impurity regions 114B are n-type impurity regions. Like the first impurity regions 114A shown in FIG. 5, the first impurity regions 114B are spaced apart from each other in the third direction y (the direction along the substrate side surface 13 of the substrate 1). In the second region 72B, a plurality of (e.g., six) second impurity regions 115B are formed in the surface portion of the base region 113, like the second impurity regions 115A shown in FIG. 5. The second impurity regions 115B are n-type impurity regions. The second impurity regions 115B are spaced apart from each other in the third direction y (the direction along the substrate side surface 14 of the substrate 1).

The first impurity regions 114B and the second impurity regions 115B may be formed to have the same depth and the same n-type impurity concentration. The n-type impurity concentration of each of the first impurity regions 114B and the second impurity regions 115B may be at least 1.0 × 10¹⁹ cm⁻³ and at most 1.0 × 10²¹ cm⁻³. The first impurity regions 114B and the second impurity regions 115B are formed with the same shape and the same area in plan view. Each of the first impurity regions 114B and the second impurity regions 115B extends in the third direction y in plan view, and is formed to have a rectangular shape whose four corners are cut off (a rectangle with rounded corners).

Each of the first impurity regions 114B forms a PN junction with the base region 113. The PN junction between the first impurity region 114B and the base region 113 forms a first Zener diode Di1B. Each of the second impurity regions 115B forms a PN junction with the base region 113. The PN junction between the second impurity region 115B and the base region 113 forms a second Zener diode Di2B. The first Zener diode Di1B and the second Zener diode Di2B are connected in reverse series via the base region 113. The first impurity region 114B and the second impurity region 115B are formed below the first external electrode 2A and the second external electrode 2B, respectively, so as to overlap with the first external electrode 2A and the second external electrode 2B in plan view. This prevents a depletion layer that extends from the PN junction between the first impurity region 114B and the base region 113 from overlapping with a depletion layer that extends from the PN junction between the second impurity region 115B and the base region 113. Thus, a bidirectional Zener diode consisting of the first Zener diode Di1B and the second Zener diode Di2B is formed in the substrate 1.

The second capacitor film 33B is formed on the third internal electrode 31B, and the fourth internal electrode 32B is formed on the second capacitor film 33B. The third internal electrode 31B may be made of a semiconductor material such as polysilicon, or may be a metallic material containing Cu or Al. In the case of a metallic material, it may contain Cu, Al, AlSi, or AlCu. The third internal electrode 31B may have a thickness of at least 1,000 Å and at most 3,000 Å (at least 100 nm and at most 300 nm).

The second capacitor film 33B is formed on the third internal electrode 31B. The second capacitor film 33B may be an SiO₂ film or an SiN film, or may be a multilayer film thereof. For example, the second capacitor film 33B may be an SiO₂/SiN multilayer film or an SiO₂/SiN/SiO₂ multilayer film. The second capacitor film 33B may be an ON film or an ONO film, or may be a multilayer film thereof. Further, the second capacitor film 33B may be an insulating film made of a high dielectric material (high-k material). Examples of high dielectric materials include aluminum oxide (Al₂O₃), tantalum pentoxide (Ta₂O₅), titanium pentoxide (Ti₃O₅), and hafnium oxide (HfO₂), as well as perovskite compounds such as strontium titanate (SrTiO₃) and barium strontium titanate (BaₓSr₁₋ₓ)TiO₃. The second capacitor film 33B may have a thickness of at least 100 Å and at most 30,000 Å (at least 10 nm and at most 3000 nm).

The fourth internal electrode 32B is formed on the second capacitor film 33B. The flat portion 322A forms the peripheral portion 326B of the fourth internal electrode 32B, which extends outward beyond the second capacitor section 30B. The fourth internal electrode 32B may be made of a semiconductor material such as polysilicon, or may be a metallic material containing Cu or Al. In the case of a metallic material, it may contain Cu, Al, AlSi, or AlCu. The fourth internal electrode 32B (the flat portion 321B) may have a thickness of at least 1,000 Å and at most 30,000 Å (at least 100 nm and at most 3000 nm).

The first insulating film 58 is formed with a first capacitor contact hole 510B that exposes the first peripheral portion 316B of the third internal electrode 31B. The first capacitor contact hole 510B is also formed in the second capacitor film 33B.

The insulating film 59 and the first insulating film 58 are further formed with a first diode contact hole 513B that exposes the first region 71B and a second diode contact hole 514B that exposes the second region 72B. As seen from the first diode contact portion 511B shown in FIG. 2, the first diode contact hole 513B is formed in a band shape elongated in the third direction y, and exposes the first Zener diodes Di1B collectively. The second diode contact hole 514B is formed in a band shape elongated in the third direction y, and exposes the second Zener diodes Di2B collectively.

The first electrode film 41B and the second electrode film 42B are formed on the first insulating film 58 and spaced apart from each other.

Referring to FIG. 9, a portion of the base portion 421B of the first electrode film 41B is formed within the first diode contact hole 513B as the first diode contact portion 511B, and another portion of the base portion 421B is formed within the first capacitor contact hole 510B. A portion of the third internal electrode 31B is formed at or within the first capacitor contact hole 510B as a lower contact portion 311B.

A portion of the base portion 421B of the second electrode film 42B is formed within the second diode contact hole 514B as the second diode contact portion 517B.

The first electrode film 41B and the second electrode film 42B may be made of a material containing Al. Such a material may be AlCu or AlSiCu, for example, and is preferably AlCu.

The surface insulating film 56 and the surface protection film 55 are formed with a first pad opening 515B that exposes the base portion 421B of the first electrode film 41B as the first pad 411B. The surface insulating film 56 and the surface protection film 55 are formed with a second pad opening 516B that exposes the base portion 421B of the second electrode film 42B as a second pad 412B.

The first pad 411B is formed with a first covering portion 561B that selectively covers the first pad 411B. The second pad 412B is formed with a second covering portion 562B that selectively covers the second pad 412B. The first covering portion 561B and the second covering portion 562B may be made of the same material as the surface insulating film 56.

The first external electrode 2A is formed within the first pad opening 515B. The first external electrode 2A is connected to the first pad 411B as the first external contact portion 381B in the first pad opening 515B. As a result, the first external electrode 2A is electrically connected to the third internal electrode 31B and the first impurity regions 114B via the first electrode film 41B.

The second external electrode 2B is formed within the second pad opening 516B. The second external electrode 2B is connected to the second pad 412B as the second external contact portion 423B in the second pad opening 516B. As a result, the second external electrode 2B is electrically connected to the fourth internal electrode 32B and the second impurity regions 115B via the second electrode film 42B.

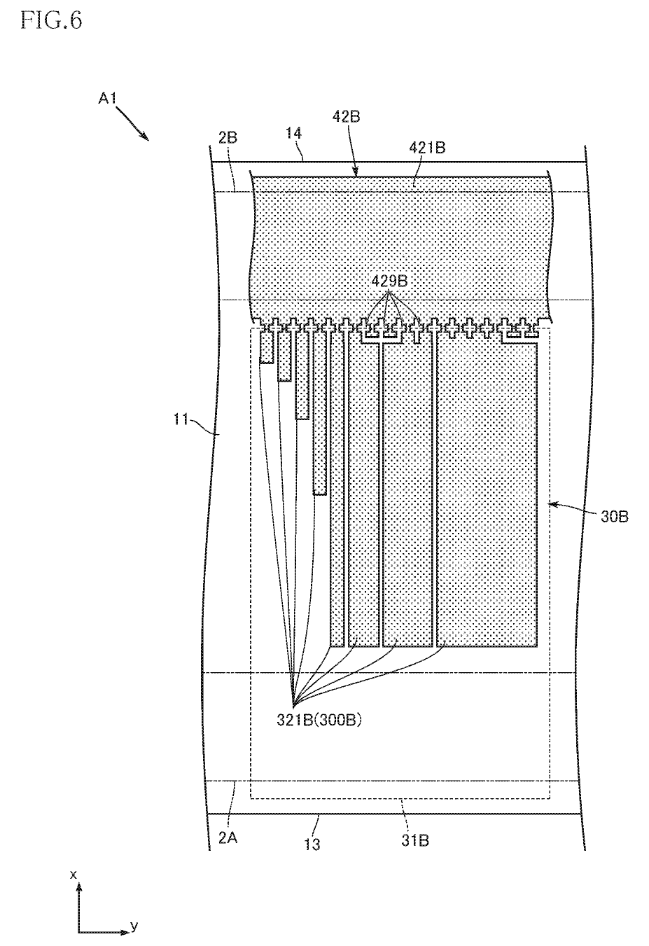

As shown in FIGS. 6, 7, and 9, the second capacitor structure 3B includes a plurality of capacitor elements 300B. The capacitor elements 300B are electrically connected in parallel to each other. The capacitance of each capacitor element 300B is not particularly limited. The capacitances of the capacitor elements 300B may be the same or different from each other. In the present embodiment, the capacitances of the capacitor elements 300B are different from each other. When the capacitances of the capacitor elements 300B are arranged in order of size, the capacitance of a capacitor element 300B may be an integer multiple of the capacitance of an adjacent capacitor element 300B, such as a factor of two.

The second electrode film 42B and the fourth internal electrode 32B of the present embodiment are formed integrally to constitute a single layer.

In the present embodiment, the fourth internal electrode 32B includes a plurality of individual portions 321B. The individual portions 321B are formed to correspond to the capacitor elements 300B, each being a constituent element of one of the capacitor elements 300B. The individual portions 321B are integrally connected to the base portion 421B of the second electrode film 42B. In present embodiment, the capacitance of each capacitor element 300B may be defined by the area of a corresponding individual portion 321B. In other words, when the areas of the individual portions 321B are arranged in order of size, the area of an individual portion 321B may be an integer multiple of an adjacent individual portion 321B, such as a factor of two.

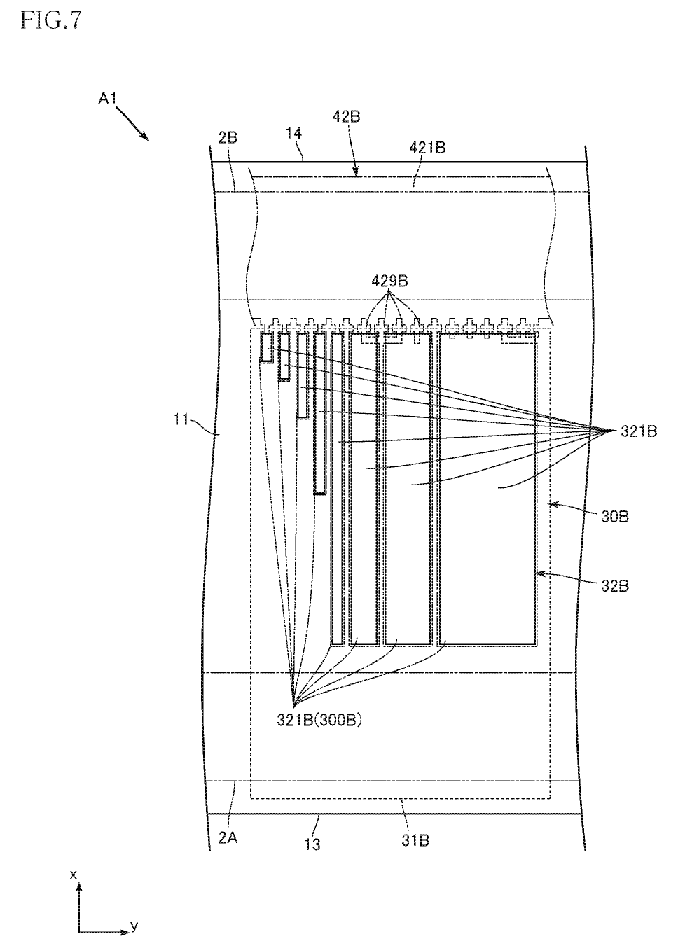

The second electrode film 42B includes a plurality of fuse portions 429B. The fuse portions 429B are individually arranged between the capacitor elements 300B and the second external electrode 2B. In other words, each of the fuse portions 429B is electrically interposed between one of the capacitor elements 300B and the second external electrode 2B. Each of the fuse portions 429B is a locally narrowed portion of the second electrode film 42B in plan view. In the illustrated example, each of the fuse portions 429B has a smaller dimension in the third direction y than each of the individual portions 321B and the base portion 421B. A plurality of fuse portions 429B may be provided between a single individual portion 321B and the base portion 421B. FIG. 7 shows a state where the fuse portions 429B are provided. The fuse portions 429B may be cut by laser irradiation during the manufacturing of the chip component A1. After the fuse portions 429B are cut, the individual portions 321B (the capacitor elements 300B) are electrically disconnected from the second external electrode 2B and no longer contribute to the capacitance of the second capacitor structure 3B.

In the present embodiment, the first internal electrode 31A and the third internal electrode 31B have the same material and thickness. The second internal electrode 32A and the fourth internal electrode 32B have the same material and thickness. The first capacitor film 33A and the second capacitor film 33B have the same material and thickness. The first electrode film 41A and the first electrode film 41B have the same material and thickness. The second electrode film 42A and the second electrode film 42B have the same material and thickness.

Next, advantages of the chip component A1 will be described.

The chip component A1 includes a first capacitor structure 3A and a second capacitor structure 3B. Thus, as compared to the case where a chip component corresponding to the first capacitor structure 3A and another chip component corresponding to the second capacitor structure 3B are separately prepared and mounted on a circuit board or the like, the mounting area can be reduced. Further, there is no need to provide wiring or the like for electrically connecting the first capacitor structure 3A and the second capacitor structure 3B.

The chip component A1 can be used to remove noise present on a power supply line in a high-frequency circuit. To achieve sufficient charging and discharging for noise removal, the capacitance of a chip capacitor is preferably in the range of several hundred pF to several nF. To remove noise from high-frequency signals of several hundred MHz or higher, a capacitor having a relatively small capacitance and a resonant frequency close to the frequency of such noise is preferable. The chip component A1 includes a first capacitor structure 3A and a second capacitor structure 3B. Since the configurations of the first capacitor structure 3A and the second capacitor structure 3B can be set separately, the specifications required for the chip component A1 can be achieved more accurately.

Using a trench capacitor as the first capacitor structure 3A can reliably increase the capacitance of the first capacitor structure 3A. Using a planar capacitor as the second capacitor structure 3B can reduce the capacitance to less than that of the first capacitor structure 3A, and can set the capacitance to a desired value more precisely. It is possible to reduce the series resistance component of the first capacitor structure 3A by appropriately setting the configurations of the walls 111 and the trenches 112 of the trench capacitor that constitutes the first capacitor structure 3A.

By providing a first capacitor structure 3A with large capacitance, the second capacitor film 33B of the second capacitor structure 3B can be made thinner while maintaining the electrostatic withstand capability of the second capacitor structure 3B.

Using a planar capacitor as the second capacitor structure 3B can reduce the inductance component and resistance component of the second capacitor structure 3B. The first capacitor structure 3A and the second capacitor structure 3B are electrically connected in parallel. Thus, even if the inductance component and resistance component of the first capacitor structure 3A increase, an increase in the inductance component and resistance component of the chip component A1 as a whole can be suppressed.

The second capacitor structure 3B includes a plurality of capacitor elements 300B. Cutting the fuse portions 429B can electrically disconnect the capacitor elements 300B from the second external electrode 2B. This makes it possible to set the capacitance of the second capacitor structure 3B more precisely, which is preferable for removing noise from high-frequency signals.

When the capacitances of the capacitor elements 300B are arranged in order of size and the capacitance of a capacitor element 300B is an integer multiple of the capacitance of an adjacent capacitor element 300B, such as a factor of two, then the capacitances of the capacitor elements 300B are configured in a ratio of 1:2:4:8:16:32: … . This makes it possible to set a wider range of capacitance values more precisely by appropriately selecting which capacitor element 300B to electrically disconnect from the second external electrode 2B.

In the present embodiment, the first internal electrode 31A and the third internal electrode 31B have the same material and thickness. Thus, in the method for manufacturing the chip component A1, the first internal electrode 31A and the third internal electrode 31B can be formed in the same step. The second internal electrode 32A and the fourth internal electrode 32B have the same material and thickness. Thus, in the method for manufacturing the chip component A1, the second internal electrode 32A and the fourth internal electrode 32B can be formed in the same step. The first capacitor film 33A and the second capacitor film 33B have the same material and thickness. Thus, in the method for manufacturing the chip component A1, the first capacitor film 33A and the second capacitor film 33B can be formed in the same step. The first electrode film 41A and the first electrode film 41B have the same material and thickness. Thus, in the method for manufacturing the chip component A1, the first electrode film 41A and the first electrode film 41B can be formed in the same step. The second electrode film 42A and the second electrode film 42B have the same material and thickness. Thus, in the method for manufacturing the chip component A1, the second electrode film 42A and the second electrode film 42B can be formed in the same step.

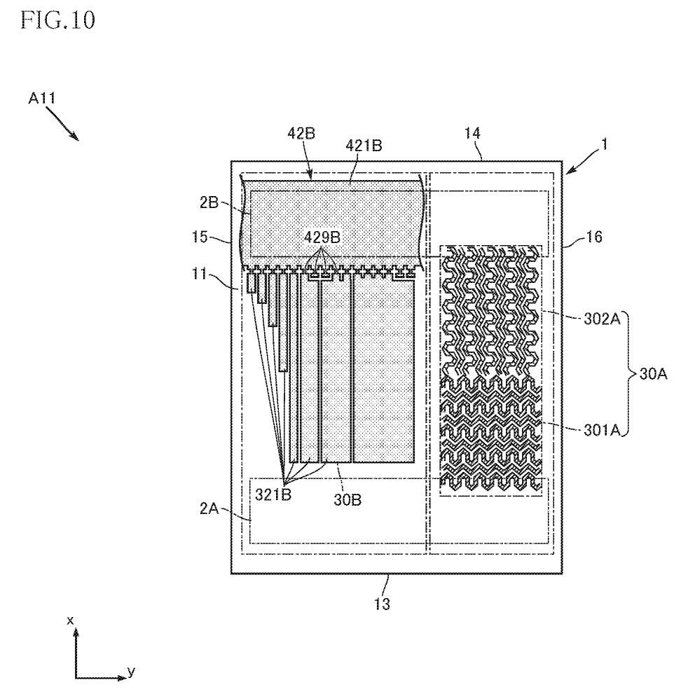

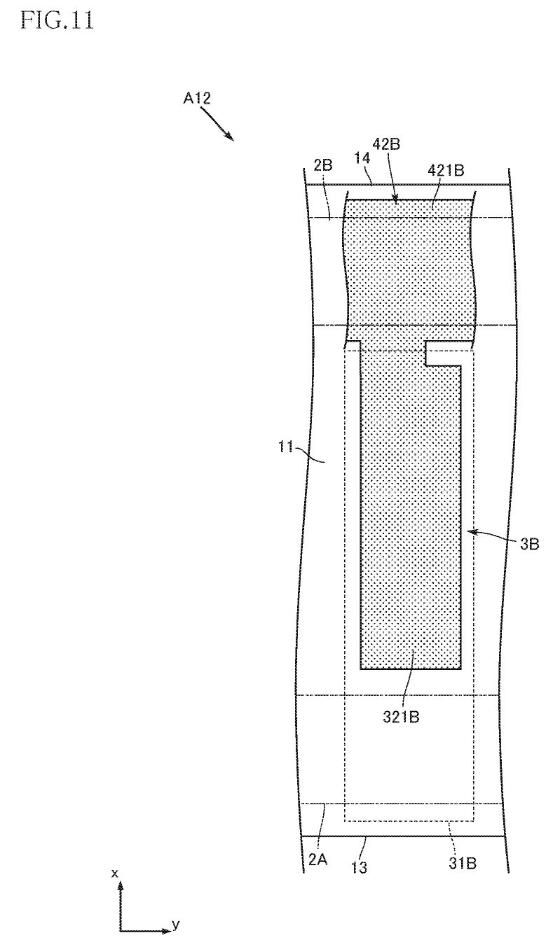

FIGS. 10 and 11 show variations of the present disclosure. In these figures, elements that are the same as or similar to the elements in the above embodiment are provided with the same reference numerals as in the above embodiment. The configurations of the elements in the variations and the embodiment can be combined as appropriate as long as the combination does not cause technical inconsistency.

FIG. 10 shows a first variation of the chip component A1. A chip component A11 of the present variation includes a single first capacitor structure 3A and a single second capacitor structure 3B.

The first capacitor structure 3A and the second capacitor structure 3B are aligned in the third direction y. In the present variation as well, the first capacitor structure 3A and the second capacitor structure 3B are electrically connected in parallel. The first capacitor structure 3A and the second capacitor structure 3B are electrically connected to each other via the first external electrode 2A. The first capacitor structure 3A and the second capacitor structure 3B are electrically connected to each other via the second external electrode 2B.

As can be understood from the present variation, the number of second capacitor structures 3B is not particularly limited.

FIG. 11 shows a second variation of the chip component A1. A chip component A12 of the present variation is different from the above example in the configuration of the second capacitor structure 3B.

The second capacitor structure 3B of the present variation does not include the capacitor elements 300B described above. The second capacitor structure 3B includes only one capacitor element 300B. The second electrode film 42B does not include the fuse portions 429B described above.

As can be understood from the present variation, the second capacitor structure 3B is not limited to the configuration including the plurality of capacitor elements 300B.

The chip component according to the present disclosure is not limited to the above embodiment. Various design changes can be made to the specific configurations of the elements in the chip component according to the present disclosure. The present disclosure includes the embodiments described in the following clauses.

Clause 1. A chip component (A1) comprising:

a substrate (1);

a first capacitor structure (3A) formed on the substrate (1); and

a second capacitor structure (3B) formed on the substrate (1),

wherein the first capacitor structure (3A) and the second capacitor structure (3B) are electrically connected in parallel, and

the first capacitor structure (3A) is a trench capacitor.

Clause 2. The chip component (A1) according to clause 1, wherein the first capacitor structure (3A) has a greater capacitance than the second capacitor structure (3B).

Clause 3. The chip component (A1) according to clause 1 or 2, wherein the substrate (1) contains a semiconductor material.

Clause 4. The chip component (A1) according to clause 3, wherein the substrate (1) contains silicon.

Clause 5. The chip component (A1) according to any of clauses 1 to 4, wherein the substrate (1) includes a substrate obverse surface (11) that is perpendicular to a first direction (z), and

the second capacitor structure (3B) is a planar capacitor along the substrate obverse surface (11).

Clause 6. The chip component (A1) according to clause 5, wherein the first capacitor structure (3A) includes a first internal electrode (31A), a second internal electrode (32A), and a first capacitor film (33A) provided between the first internal electrode (31A) and the second internal electrode (32A).

Clause 7. The chip component (A1) according to clause 6, wherein the second capacitor structure (3B) includes a third internal electrode (31B), a fourth internal electrode (32B), and a second capacitor film (33B) provided between the third internal electrode (31B) and the fourth internal electrode (32B).

Clause 8. The chip component (A1) according to clause 7, wherein the first internal electrode (31A) is made of the same material as the third internal electrode (31B).

Clause 9. The chip component (A1) according to clause 7 or 8, wherein the second internal electrode (32A) is made of the same material as the fourth internal electrode (32B).

Clause 10. The chip component (A1) according to any of clauses 7 to 9, wherein the first capacitor film (33A) is made of the same material as the second capacitor film (33B).

Clause 11. The chip component (A1) according to any of clauses 1 to 10, further comprising a first external electrode (2A) and a second external electrode (2B).

Clause 12. The chip component (A1) according to clause 11, wherein the first capacitor structure (3A) and the second capacitor structure (3B) are electrically connected to each other via the first external electrode (2A).

Clause 13. The chip component (A1) according to clause 11 or 12, wherein the first capacitor structure (3A) and the second capacitor structure (3B) are electrically connected to each other via the second external electrode (2B).

Clause 14. The chip component (A1) according to any of clauses 11 to 13, wherein the second capacitor structure (3B) includes a plurality of capacitor elements (300B) that are electrically connected in parallel to each other, and a plurality of fuse portions (429B) individually arranged between the plurality of capacitor elements (300B) and the second external electrode (2B).

Clause 15. The chip component (A1) according to any of clauses 1 to 14, wherein the first capacitor structure (3A) comprises two first capacitor structures (3A) located on opposite sides of the second capacitor structure (3B) to flank the second capacitor structure (3B) in plan view.

1. A chip component comprising:
a substrate;
a first capacitor structure formed on the substrate; and
a second capacitor structure formed on the substrate,
wherein the first capacitor structure and the second capacitor structure are electrically connected in parallel, and
the first capacitor structure is a trench capacitor.

2. The chip component according to claim 1, wherein the first capacitor structure has a greater capacitance than the second capacitor structure.

3. The chip component according to claim 1, wherein the substrate contains a semiconductor material.

4. The chip component according to claim 3, wherein the substrate contains silicon.

5. The chip component according to claim 1, wherein the substrate includes a substrate obverse surface that is perpendicular to a first direction, and
the second capacitor structure is a planar capacitor along the substrate obverse surface.

6. The chip component according to claim 5, wherein the first capacitor structure includes a first internal electrode, a second internal electrode, and a first capacitor film provided between the first internal electrode and the second internal electrode.

7. The chip component according to claim 6, wherein the second capacitor structure includes a third internal electrode, a fourth internal electrode, and a second capacitor film provided between the third internal electrode and the fourth internal electrode.

8. The chip component according to claim 7, wherein the first internal electrode is made of a same material as the third internal electrode.

9. The chip component according to claim 7, wherein the second internal electrode is made of a same material as the fourth internal electrode.

10. The chip component according to claim 7, wherein the first capacitor film is made of a same material as the second capacitor film.

11. The chip component according to claim 1, further comprising a first external electrode and a second external electrode.

12. The chip component according to claim 11, wherein the first capacitor structure and the second capacitor structure are electrically connected to each other via the first external electrode.

13. The chip component according to claim 11, wherein the first capacitor structure and the second capacitor structure are electrically connected to each other via the second external electrode.

14. The chip component according to claim 11, wherein the second capacitor structure includes a plurality of capacitor elements that are electrically connected in parallel to each other, and a plurality of fuse portions individually arranged between the plurality of capacitor elements and the second external electrode.

15. The chip component according to claim 1, wherein the first capacitor structure comprises two first capacitor structures located on opposite sides of the second capacitor structure to flank the second capacitor structure in plan view.
